(19) United States
(12) Patent Application Publication
(10) Pub. No.: US 2004/0262373 A1
(43) Pub. Date: Dec. 30, 2004

(54) Solder ball mounting method and apparatus therefor

(75) Inventor: Kensei Murata, Kanazawa-shi (JP)

Correspondence Address: SUGHRUE MION, PLLC, 2100 PENNSYLVANIA AVENUE, N.W., SUITE 800, WASHINGTON, DC, 20037, US

(73) Assignee: SHIBUYA KOGYO CO., LTD

(21) Appl. No.: 10/875,285

(22) Filed: Jun. 25, 2004

(30) Foreign Application Priority Data
Jun. 26, 2003 (JP) P2003-182859

(51) Int. Cl. B23K 1/00

(52) U.S. Cl. 228/246; 228/41

(57) ABSTRACT

A flux is supplied from a flux transfer head having a flux transfer pin to a predetermined position on a substrate, and then a solder ball is mounted on the predetermined position by a solder ball mounting head having a suction nozzle. The solder ball mounting head and the flux transfer head are provided alternately on a head supporter. When the rotation of the head supporter is stopped, sucking a solder ball suction by the suction nozzle, depositing the flux on a free end of the flux transfer pin, transferring the flux to the substrate by the flux transfer pin, and mounting the solder ball on the predetermined position by the ball mounting head, and examining whether the solder ball exists on the suction nozzle by which the ball mounting operation has just carried out are executed.

The present application is based on Japanese Patent Application No. 2003-182859, which is incorporated herein by reference.

### BACKGROUND OF THE INVENTION

1. Field of the Invention

The present invention relates to a solder ball mounting method and an apparatus therefor, which have been developed aiming principally at obtaining a single-solder-ball mounting method and an apparatus therefor.

2. Description of the Related Art

A case where one solder ball is mounted on a substrate by a solder ball mounting apparatus will be described. In a related apparatus of this kind, one ball mounting head and one flux transfer head are formed so that each of these heads can be laterally moved as disclosed in JP2000-58586A. In such an apparatus, flux was deposited on a flux transfer pin at the solder ball mounting time, and transferred to a substrate at the solder ball suction time.

A single-solder-ball mounting machine demands an increase in operational speed (reduction of the tact time). In the above-described related art apparatus, the takeout of the flux and the mounting of the solder ball, and the transfer of the flux and the takeout of the solder ball can be carried out at once but a difference between the time needed for an operation of a flux transfer head and that needed for an operation of a ball mounting head constitutes every time the waiting time for the apparatus. This causes an increase in the tact time of the apparatus. Although the success or failure of the takeout of the solder ball is detected, the detection of the success or failure of a small-diameter solder ball takes much time. This also constitutes one of the factors of causing an increase in the tact time of the apparatus.

For example, making an attempt to detect a solder ball mounting error causes the time needed for this detection operation to be simply added to the total time for carrying out a solder mounting operation. This poses a problem of a decrease in the operation efficiency. Incidentally, a solder ball mounting operation takes most time in a solder ball mounting apparatus, and the time needed to carry out the deposition and transfer of flux is short in the existing circumstances as compared with that needed to carry out the solder ball mounting and suction operations.

### SUMMARY OF THE INVENTION

The present invention aims at providing a solder ball mounting method and an apparatus therefor capable of carrying out even a solder ball mounting error detection operation in parallel with other operation, not causing this error detection operation to generate a time loss, and capable of promoting a further increase in the operation efficiency.

To solve the above problems, a first invention employs the following means for the solder ball mounting method.

First, a solder ball mounting method comprising the steps of supplying flux from at least one flux transfer head having a flux transfer pin to a predetermined position on a substrate, and then mounting a solder ball on the predetermined position by at least one solder ball mounting head having a suction nozzle.

Secondly, the solder ball mounting head and flux transfer head are provided alternately on a head supporter, and the head supporter intermittently rotates so that supplying flux and mounting the solder ball are executed alternately.

Thirdly, a solder ball suction operation by the suction nozzle, an operation for depositing the flux on the free end of the flux transfer pin, an operation for transferring the flux to the substrate by the flux transfer pin, an operation for mounting the solder ball on the substrate by the ball mounting head, and an operation for examining whether the solder ball exists on the suction nozzle by which the ball mounting operation has just carried out are executed when the rotation of the head supporter is stopped. In such operations, a first mode comprises transferring the flux to the substrate and examining the existence of the solder ball on the suction nozzle by which the ball mounting operation has just carried out executed at the same time, and a second mode comprises sucking a solder ball, depositing the flux on the free end of the flux transfer pin and mounting the solder ball on the predetermined position executed at the same time. The first mode and the second mode are executed alternately by each pair of nozzles.

A second invention relates to an improvement in the method according to the first invention, which additionally has the step of examining whether the solder ball exists on the suction nozzle by which the ball suction operation has just carried out, when the rotation of the flux transfer head and solder ball mounting head are stopped.

A third invention is an invention in which the first invention is formed into an apparatus, in which solder ball mounting apparatus employs the following means.

First, the apparatus is provided with a solder ball mounting head having a suction nozzle adapted to suck a solder ball thereto and release the solder ball in a predetermined position, and a flux transfer head adapted to bring the flux transfer pin, to the free end of which the flux is deposited, into contact with a predetermined portion of the substrate and supply the flux thereto.

Secondly, a solder ball mounting apparatus is formed which is adapted to transfer the flux on a predetermined position on the substrate, and then mount a solder ball on the predetermined position by the solder ball mounting head.

Thirdly, the solder ball mounting head and flux transfer head are provided plurally and alternately on the head supporter.

Fourthly, a supply unit which supplies a solder ball to the suction nozzle, a flux supply unit which supplies flux to the flux transfer pin, and a mounting unit which mounts the solder ball on the substrate are allocated in the stop positions for the flux transfer head and ball mounting head.

A fourth invention relates to an improvement in the third invention in which an examining unit which examines whether the sucking of the solder ball by the suction nozzle was done or not is allocated additionally in a stop position other than the stop positions for the flux transfer head and solder ball mounting head used in the third invention.

### BRIEF DESCRIPTION OF THE DRAWINGS

In the accompanying drawings:

FIG. 1 is a perspective view showing a solder ball mounting head and a flux transfer head;

FIG. 2 is a schematic arrangement drawing showing an example of a solder ball mounting apparatus utilized by the present invention;

FIGS. 3A to 3D are explanatory drawings showing a fixed plate and a rotary plate, wherein FIG. 3A is an explanatory drawing of these two plates in a combined state, FIG. 3B is a plan view of the fixed plate, FIG. 3C is a bottom view of the fixed plate, and FIG. 3D is a plan view of the rotary plate;

FIG. 4 is a partially sectioned explanatory drawing in front elevation showing the relation between flux transfer heads and solder ball mounting heads;

FIG. 5 is an explanatory drawing in plan showing the same relation; and

FIG. 6 is a right side explanatory drawing showing a lift mechanism for a solder ball suction lift unit.

### DETAILED DESCRIPTION OF THE PREFERRED EMBODIMENTS

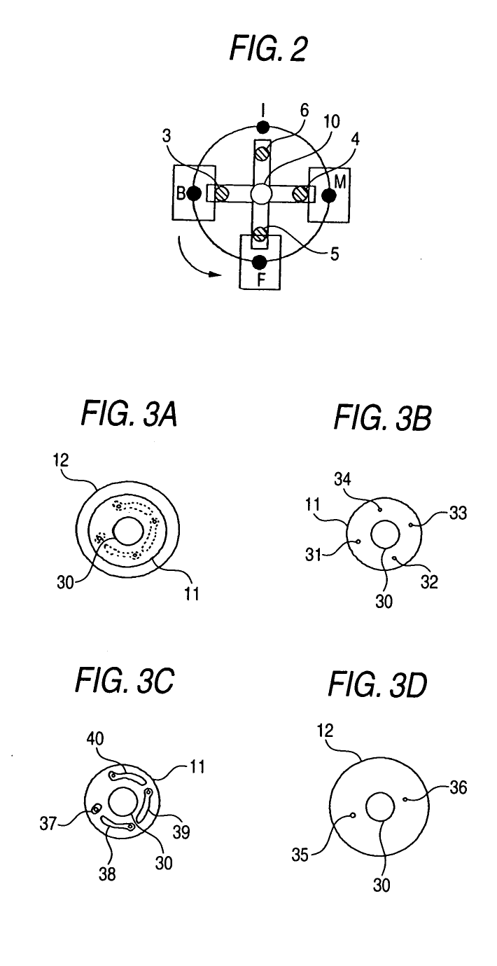

A mode of embodiment of the present invention will now be described with an embodiment thereof with reference to the drawings. FIG. 2 is a schematic arrangement drawing showing an example of the solder ball mounting apparatus in which the present invention is utilized.

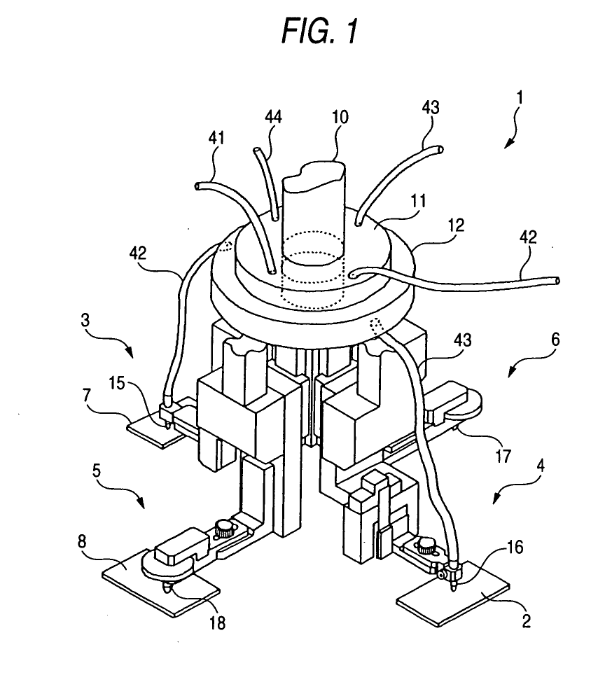

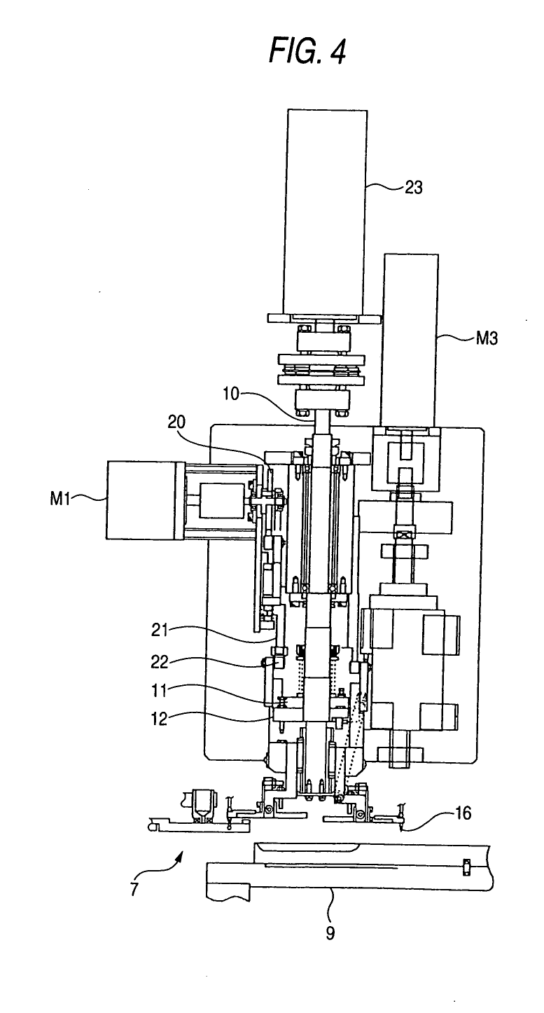

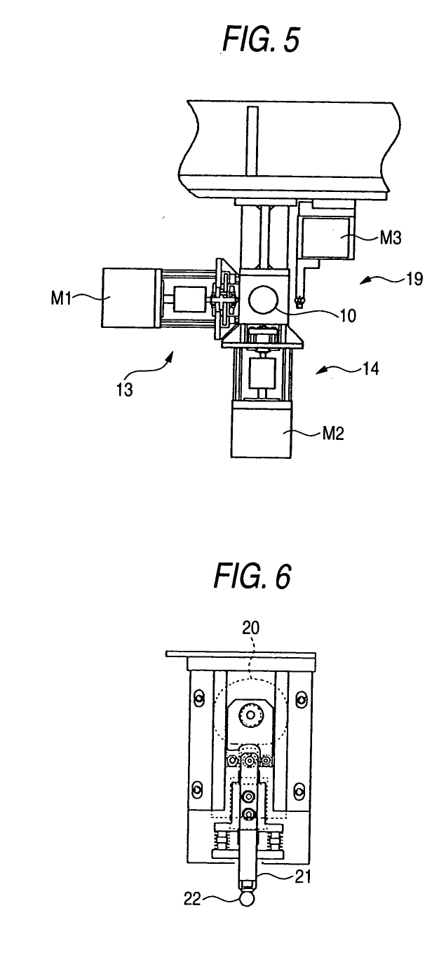

As shown in FIG. 1 and FIG. 2, a solder ball mounting apparatus 1 has heads 3, 4 for sucking and holding a solder ball and mounting the solder ball on a substrate 2, heads 5, 6 for transferring flux to the substrate 2, a tool rotating shaft 10 to which the solder ball mounting heads and flux transfer heads are fixed, a unit 7 for supplying the solder ball to the solder ball mounting heads 3, 4, a unit 8 for supplying flux to the flux transfer heads 5, 6, and an X-Y stage 9 (the X-Y stage 9 is shown in FIG. 4) on which the substrate 2 is suction-supported for a flux transfer operation and a solder mounting operation.

As shown in FIG. 4, the tool rotating shaft 10 is rotated intermittently by an angle of rotation of 90 degrees at a time by a rotating motor 23. The shaft can, of course, be rotated in the opposite direction as well.

On a side surface of a lower portion of the tool rotating shaft 10, the flux transfer heads 5, 6 and solder ball mounting heads 3, 4 are provided alternately as shown in FIG. 1 and FIG. 2, in such a manner that the two pairs of heads can be moved vertically in an upwardly spring-urged state. The flux transfer head 5 and flux transfer head 6, and the solder ball mounting head 3 and solder ball mounting head 4 are fixed in a diagonally opposed state respectively.

At the lower ends of the solder ball mounting heads 3, 4, suction nozzles 15, 16 for sucking a solder ball and mounting the same on the substrate 2 are provided. At the lower ends of the flux transfer heads 5, 6, transfer pins 17, 18 are provided. The suction nozzles 15, 16 are connected to a suction pump, a vacuum break air circuit, a solder ball suction examination unit and a solder ball carry-back examination unit (which are not shown).

The suction nozzles 15, 16 are rotated with the tool rotating shaft 10. Therefore, the tool rotating shaft 10 is mounted with an air regulating mechanism including a fixed plate 11 and a rotary plate 12 so as to control the connection of the tool rotating shaft to the suction nozzles 15, 16.

The fixed plate 11 of the air regulating mechanism is mounted on the tool rotating shaft 10 by inserting the same shaft 10 into a fitting hole 30, but in a condition not to receive the rotation of the tool rotating shaft 10, an outer wall of the fixed plate 11 being provided with through holes 31, 32, 33, 34. Connecting pipes 41, 42, 43, 44 are joined to the through holes 31, 32, 33, 34. The connecting pipe 41 is joined to the suction pump via a switch valve, the connecting pipe 42 to the suction pump via the solder ball suction examination unit, the connecting pipe 43 to the suction pipe and vacuum break air source via a change-over valve, and the connecting pip 44 to the suction pump via the solder ball carry-back examination unit.

On the other hand, the rotary plate 12 is mounted on the tool rotating shaft 10 so that the rotary plate can be rotated with the shaft 10. The rotary plate is provided with through holes 35, 36. The through holes 35, 36 are joined to the connecting pipes 42, 43, and the other ends of the connecting pipes 42, 43 to the suction nozzles 15, 16.

The contact surfaces of the fixed plate 11 and rotary plate 12 are provided with recesses 37, 38, 39, 40 for regulating the “ON” time of the through holes of both of these plates. In this embodiment, the recesses 37, 38, 39, 40 are formed only in inner contact surfaces of the through holes 31, 32, 33, 34 of the fixed plate 11.

The positions of the tool rotating shaft 10 which serve as stop positions for the solder ball mounting heads 3, 4 and flux transfer heads 5, 6 fixed to the tool rotating shaft 10 include as shown in FIG. 2 a position B on the left side of the tool rotating shaft 10 in which a solder ball supply unit is to be provided, a position F on the front side of the shaft in which a unit for supplying flux to the transfer pins 17, 18 and a unit for ascertaining the suction of a solder ball to the suction nozzles 15, 16 is to be provided, a position M on the right side of the shaft in which a solder ball mounting unit is to be provided, and a position I on the rear side of the shaft in which a remains examination unit (for ascertaining the existence of a solder ball on the solder ball suction nozzles) is to be provided.

A solder ball supply unit 7 and a ball suction lift unit 13 are provided in the left side position B serving as a solder ball supply position, the flux supply unit 8 and flux supply lift unit 14 in the front side position F serving as a position for supplying flux to the flux transfer pins 17, 18, the X-Y stage 9 and a mounting lift unit 19 which support the substrate 2 on which the solder ball is mounted in the right side position M serving as a solder ball mounting position, these units being provided so that these units can be operated independently of each other.

As shown in FIG. 4, the solder ball supply unit 7 is a unit for taking out a solder ball one by one from a solder ball storage unit (not shown) The solder ball supply unit 7 is fixed to a base to which the tool rotating shaft 10 is mounted rotatably.

As shown in FIG. 6, in the ball suction lift unit 13, a cam 20 rotated by a motor M1 presses down a roller 22, which is provided at upper ends of the solder ball mounting heads 3, 4 urged upward constantly, via a pressure member 21. The cam 20 is formed to such a shape that permits the solder ball mounting heads 3, 4 to lower and return to original positions thereof in one turn of the cam.

The flux supply unit 8 is fixed to the non-rotating portion (base) of the tool rotating shaft 10 which is on the outer side thereof, and may be a general flux supply unit. The flux supply lift unit 14 is also formed in the same manner as the solder ball suction lift unit 13, and adapted to press down the roller 22 provided at the uppermost ends of the flux transfer heads 5, 6, via the pressure member 21 lowered by a motor M2 by utilizing the cam 20.

The mounting lift unit 19 is adapted to press down upper end surfaces of the solder ball mounting heads 3, 4 and flux transfer heads 5, 6 by a motor M3, and enables a precise position control operation by utilizing a ball screw and a nut. Furthermore, in the solder ball suction unit and a flux application unit, the roller 22 fixed to the flux transfer heads is pressed down but, in the mounting lift unit 19, the upper surfaces of the flux transfer heads are pressed down directly not via the roller 22 so as to improve the accuracy.

The tool rotating shaft 10 is adapted to stop the solder ball mounting heads and flux transfer heads at the necessary positions B, F, M, I as the shaft is rotated intermittently in the direction shown by an arrow in FIG. 2, and carry out each kind of operation. A basic part of each operation will be described.

The position B on the left side of the tool rotating shaft is a position of the the solder ball supply unit as shown in FIG. 2, in which the solder ball supply unit 7 and solder ball suction lift unit 13 are provided. In the solder ball supply unit, the solder ball suction lift unit 13 lowers the solder ball suction heads 3, 4 when the solder ball mounting heads 3, 4 stop in an upper position, and sucks and holds a solder ball from the solder ball supply unit 7.

The position F on the front side of the tool rotating shaft 10 is a position of the flux supply unit and solder ball suction ascertaining unit, in which the flux supply unit 8 and flux supply lift unit 14 are provided. In this front position F, the flux supply lift unit 14 lowers the flux transfer heads 5, 6 when the flux transfer heads 5, 6 stop in an upper position, and the flux supply unit 8 supplies flux to the transfer pins 17.

When the solder ball mounting heads 3, 4 stop in the front position F, the same position becomes a position of the solder ball suction ascertaining unit, and the ascertainment of whether the suction nozzles 15, 16 sucked a solder ball or not is made by detecting the variation of an internal pressure and a flow rate in the suction nozzles 15, 16 by using a pressure sensor and a flow sensor.

The position M on the right side of the tool rotating shaft 10 is a position of the solder ball mounting unit. In this right position M, the X-Y stage 9 supporting the substrate 2 on which the solder ball is mounted is provided below the tool rotating shaft 10. In this embodiment, the substrate 2 is set manually. The substrate 2 may also be automatically supplied and discharged.

When the flux transfer heads 5, 6 stop in the right position M, the flux transfer heads 5, 6 transfer flux to the substrate 12 on the X-Y stage 9 by the mounting lift unit 19. The height of a solder ball mounting surface is then detected.

When the solder ball mounting heads 3, 4 then stop in the position M on the right side of the tool rotating shaft 10, the solder ball is mounted on the substrate 2 as the solder ball mounting operation is controlled on the basis of the height of the detected solder ball mounting surface by the mounting lift unit 19. When a failure in the suction of the solder ball was proved during the solder ball suction ascertaining operation in the front position F, the solder ball mounting operation by the solder ball mounting heads 3, 4 is not carried out but is carried out by the solder ball mounting heads stopped in the position next time.

When the solder ball mounting heads 3, 4 stop in the position I on the rear side of the tool rotating shaft 10, the solder ball mounting heads 3, 4 are examined whether a ball exists thereon or not. The rear position I comes to serve as a position for providing a remains examination unit therein. This examination is also carried out by ascertaining whether the suction nozzles 15, 16 suck a solder ball or not by detecting an internal pressure and a flow rate in the suction nozzles 15, 16 by using a pressure sensor and a flow sensor. When the remains examination, unit keeps sucking a solder ball, the tool rotating shaft 10 is turned reversely, and an attempt to carry out the solder ball mounting operation is made again. When the solder ball mounting operation cannot be carried out even though an attempt to carry out the same operation is made predetermined number of times, the solder ball mounting heads are erroneously stopped. When the flux is transferred to the substrate in this embodiment, the existence of the solder ball on the suction nozzles by which the solder ball suction operation has just carried out is examined in parallel with the flux transfer operation, and the existence of the solder ball on the suction nozzles by which the solder ball mounting operation has just carried out is also examined. When the solder ball is mounted on the substrate, the sucking of a solder ball thereto and the depositing of flux on the end of the flux transfer pin are done in parallel with the solder ball mounting operation.

An arrangement in which the solder ball supply unit and flux supply unit in this embodiment are replaced with each other may be employed so that the supplying of flux to the flux transfer pin during a flux transfer operation, the sucking of a solder ball to the suction nozzle and the examining of the existence of the solder ball on the suction nozzle by which the solder ball mounting operation has just carried out are executed. These operations are repeated in order by carrying out the same operations in the respective positions at once. Although this embodiment is based on a single-solder-ball mounting apparatus, the embodiment can, of course, be utilized for a plural-solder-ball mounting apparatus. The present invention is not limited to this embodiment having two each flux transfer heads and solder ball mounting heads. The flux transfer heads and solder ball mounting heads may be provided more, and the number of the stop positions may be set in accordance with the increased number of flux transfer heads and solder ball mounting heads.

The present invention provides a solder ball mounting method, wherein a solder ball mounting head and a flux transfer head are provided plurally and alternately on an intermittently rotating head supporter, a solder ball suction operation by the suction nozzle, an operation for depositing the flux on a free end of flux transfer pin, an operation for transferring the flux to the substrate by the flux transfer pin, an operation for mounting the solder ball on the predetermined position on a substrate by the ball mounting head, and an operation for examining the existence of the solder ball by which the ball mounting operation has just carried out are executed when the rotation of the head supporter is stopped. This method enables even a mistaken ball mounting operation examining operation to be carried out in parallel with other operation, and proves that this method is a solder ball mounting method which does not cause an erroneous operation to generate a time loss, and which is capable of promoting a further increase in the operation efficiency.

The following is an effect of the invention defined in Claim 3. Even an operation for examining whether a solder ball exists or not on the suction nozzles by which a solder ball suction operation has just carried out can be executed in parallel with other operation when the rotation of the head supporter is stopped. This method proves to be a method which enables a mistaken ball mounting operation examining operation to be carried out in parallel with other operation, and proves that this method is a solder ball mounting method which does not cause even an erroneous operation to generate a time loss, and which is capable of promoting a further increase in the operation efficiency.

The following is an effect of the invention defined in Claim 7. This solder ball mounting apparatus is formed by providing a ball mounting head and a flux transfer head plurally and alternately on an intermittently rotating supporter, and allocating a unit for supplying a solder ball to a suction nozzle, a unit for supplying flux to the flux transfer pin, and a unit for mounting a solder ball on a substrate in stop positions for the flux transfer head and solder mounting head. Therefore, this apparatus becomes capable of processing in parallel with each other various kinds of operations for mounting the solder ball on the substrate.

The following is an effect of the invention defined in Claim 8. When a unit for examining whether a solder ball exists or not on the suction nozzle is allocated in a stop position other than the stop positions for the flux transfer heads and solder ball mounting heads used in the invention defined in Claim 7, a solder ball mounting apparatus which does not cause an erroneous operation to generate a time loss, and which is capable of promoting a further increase in the operation efficiency, is obtained.

What is claimed is:

1. A solder ball mounting method adapted to supply flux from at least one flux transfer head having a flux transfer pin to a predetermined position on a substrate and then mount a solder ball on the predetermined position by at least one solder ball mounting head having a suction nozzle, the solder ball mounting head and flux transfer head are provided alternately on a head supporter, comprising:
sucking a solder ball by the suction nozzle;
depositing the flux on a free end of the flux transfer pin;
transferring the flux to the substrate by the flux transfer pin; and
mounting the solder ball on the predetermined position by the ball mounting head,
wherein the method are executed when the rotation of the head supporter is stopped.

2. The solder ball mounting method according to claim 1, further comprising examining whether the solder ball exists on the suction nozzle by which the ball mounting operation has just carried out.

3. The solder ball mounting method according to claim 1, further comprising examining whether the solder ball exists on the suction nozzle by which the ball suction operation has just carried out.

4. The solder ball mounting method according to claim 2, wherein the head supporter is turned reversely to carry out the solder ball mounting operation is made again, when the remains examination unit keeps sucking the solder ball.

5. The solder ball mounting method according to claim 2, wherein:
a first mode comprising transferring the flux to the substrate and examining the existence of the solder ball on the suction nozzle by which the ball mounting operation has just carried out executed at the same time;
a second mode comprising sucking a solder ball, depositing the flux on the free end of the flux transfer pin and mounting the solder ball on the predetermined position executed at the same time; and
the first mode and the second mode are executed alternately by each pair of nozzles.

6. The solder ball mounting method according to claim 1, wherein the head supporter comprises two flux transfer heads and two solder ball mounting heads fixed in a diagonally opposed state respectively and rotates intermittently so that forms the stop positions by an angle of every 90 degrees.

7. A solder ball mounting apparatus provided with a ball mounting head having a suction nozzle adapted to suck a solder ball and release the same in a predetermined position, and a flux transfer head adapted to bring a flux transfer pin, on the ends of which flux is deposited, into contact with predetermined positions on a substrate, a solder ball being mounted on the predetermined position after the flux is transferred to the predetermined position on the substrate, the solder ball mounting head and the flux transfer head are provided plurally and alternately on an intermittently rotating head supporter, comprising:
a supply unit supplying a solder ball to the suction nozzle;
a flux supply unit supplying flux to the flux transfer pin; and
a mounting unit mounting the solder ball on the substrate,
wherein the units are allocated in stop positions for the solder ball mounting head and the flux transfer head.

8. The solder ball mounting apparatus according to claim 7, wherein an examining unit examining whether the sucking of a solder ball was done or not by the suction nozzle is allocated in a stop position other than the stop positions for the flux transfer head and solder ball mounting head.

9. The solder ball mounting apparatus according to claim 8, wherein the rotating head supporter turns reversely to carry out the solder ball mounting operation made again, when the remains examination unit keeps sucking the solder ball.

10. The solder ball mounting apparatus according to claim 7, wherein two flux transfer heads and two solder ball mounting heads are fixed in a diagonally opposed state respectively on the mounting head supporter, and the stop positions are allocated by an angle of every 90 degrees.
